(19) United States
(12) Patent Application Publication
(10) Pub. No.: US 2026/0190839 A1
(43) Pub. Date: Jul. 2, 2026

(54) DISPLAY DEVICE

(71) Applicant: LG Display Co., Ltd., Seoul (KR)

(72) Inventors: Youngsub SHIN, Goyang-si (KR); Seungcheol YOU, Seoul (KR); ChaeKyung LIM, Seoul (KR)

(73) Assignee: LG Display Co., Ltd., Seoul (KR)

(21) Appl. No.: 19/432,503

(22) Filed: Dec. 24, 2025

(30) Foreign Application Priority Data
Dec. 31, 2024 (KR) 10-2024-0202379

(51) Int. Cl. H10K 59/80; H10K 59/38; H10K 59/40

(52) U.S. Cl. CPC H10K 59/8792; H10K 59/38; H10K 59/40

(57) ABSTRACT

A display device can include a substrate having a display area in which a plurality of sub-pixels is disposed, a light emitting element disposed on the substrate so as to correspond to each of the plurality of sub-pixels, an encapsulation layer disposed on the light emitting element, a touch sensing layer disposed on the encapsulation layer and including a plurality of touch electrodes, a plurality of color filters disposed on the touch sensing layer so as to correspond to each of the plurality of sub-pixels, and a black matrix having a triple-layered structure in which a first layer, a second layer, and a third layer are sequentially stacked.

### CROSS-REFERENCE TO RELATED APPLICATIONS

This application claims priority to Korean Patent Application No. 10-2024-0202379 filed on December 31, 2024, in the Korean Intellectual Property Office, the entire disclosure of which is hereby expressly incorporated by reference.

### BACKGROUND

### Field

The present disclosure relates to a display device, and more particularly, to a display device with low reflectance and improved display quality.

### Discussion of the Related Art

In general, an organic light emitting display device includes an anode, a cathode, and an organic light emitting layer disposed therebetween. As the cathode is formed using a metal material having a high reflectance, external light is reflected by the metal material to deteriorate reflection visibility and a contrast ratio. Accordingly, in order to reduce reflection due to external light, a polarizing plate for absorbing external light is disposed under the cover member. The polarizing plate is a film having a predetermined level of light transmittance and absorbs external light and reflected light thereof to prevent a decrease in contrast ratio.

Recently, as interest in flexible and slim display devices has increased, a display device to which a relatively thin coated polarizing film is applied, instead of a thick polarizing plate, has been proposed. However, the coated polarizing film also can have a problem in that the thickness is thick, and when the thickness is reduced, the function and display quality of the polarizing film can be deteriorated.

Therefore, a Color Filter on Encapsulation (CoE) structure has been proposed, instead of using a polarizing plate or a coated polarizing film. The CoE structure according to the related art is a structure in which a black matrix is disposed on an encapsulation layer so as to correspond to a non-emission area, and a color filter is disposed so as to correspond to the emission area. In the CoE structure, the thickness of the display device can be reduced, and the transmittance is easily adjusted, so that external light and reflected light can be absorbed without lowering the luminous efficiency.

### SUMMARY OF THE DISCLOSURE

In a CoE structure of a display device, a black matrix is formed to overlap the touch line of a touch sensing layer, and there can be a problem that the lower touch line is reflected. In addition, the CoE structure transmits light emitted from the light emitting element well, but can have a disadvantage in that the reflectance is slightly higher than that of the polarizing plate.

Accordingly, an object to be achieved by the present disclosure is to provide a display device with excellent display quality by lowering a reflectance while maintaining a high luminance and improving a problem in which a touch line is visually recognized.

Another object to be achieved by the present disclosure is to provide a display device, which address the limitations and disadvantages associated with the related art including the CoE structures of the related art.

Meanwhile, a multimedia function of a mobile terminal has recently been improved. Accordingly, an optical electronic device such as a camera and/or various sensors is disposed in a partial area of the screen of the display device. These optical electronic devices need to be arranged to receive light such as infrared light for operation of the optical electronic device without being exposed to the front to implement a full screen.

However, in the CoE structure, the black matrix is configured to absorb light in a wide wavelength range to reduce reflectance, and there can be a problem in that light such as infrared light is not normally received as an optical electronic device.

Accordingly, another object to be achieved by the present disclosure is to provide a display device with an optical electronic device that transmits light in an infrared region well and blocks light in a visible light region to facilitate the operation of the optical electronic device and has a low reflectance.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a display area in which a plurality of sub pixels is disposed, a light emitting element disposed on the substrate so as to correspond to each of the plurality of sub pixels, an encapsulation layer disposed on the light emitting element, a touch sensing layer disposed on the encapsulation layer and including a plurality of touch electrodes, a plurality of color filters disposed on the touch sensing layer so as to correspond to each of the plurality of sub pixels, and a black matrix disposed on the touch sensing layer so as to partition the plurality of color filters from each other and having a triple-layered structure in which a first layer, a second layer, and a third layer are sequentially stacked. The display area includes an optical area through which light is transmitted and a normal area surrounding the optical area, and in the normal area, a refractive index of each of a first layer and a third layer of the black matrix is smaller than a refractive index of a second layer.

Other detailed matters of the embodiments are of the present disclosure included in the detailed description and the drawings.

The display device according to aspects of the present disclosure has an advantage of excellent display quality because the luminance is high, the reflectance is low, and the touch line is not visually recognized.

The display device according to aspects of the present disclosure has the advantage that the light in the infrared region is well transmitted in the area in which the optical electronic device is disposed, and the light in the visible light region is blocked, so that the operation of the optical electronic device is smooth and the external light reflectance is low.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a display device according to an embodiment of the present disclosure.

FIG. 2 is an enlarged plan view illustrating placement of sub-pixels in a normal area in a display device according to an example embodiment of the present disclosure.

FIG. 3 is an enlarged plan view illustrating placement of sub-pixels in an optical area in a display device according to an embodiment of the present disclosure.

FIG. 4 is a cross-sectional view illustrating a cross-sectional structure of a partial pixel area disposed in a normal area in a display device according to an embodiment of the present disclosure.

FIG. 5 is a cross-sectional view illustrating a cross-sectional structure of some sub-pixels disposed in an optical area in a display device according to an embodiment of the present disclosure.

FIGS. 6A to 6C are schematic diagrams illustrating various structures of a black matrix.

FIG. 7A is a sub-pixel photograph of a conventional display device including a black matrix of a single layer.

FIG. 7B is a sub-pixel photograph of a display device including a black matrix having a triple-layered structure according to an embodiment of the present disclosure.

FIG. 8 is a cross-sectional view illustrating a cross-sectional structure of some sub-pixels disposed in an optical area in a display device according to another embodiment of the present disclosure.

FIG. 9 is a graph showing examples of a transmittance according to the configuration of a black matrix.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device/apparatus according to all embodiments of the present disclosure are operatively coupled and configured.

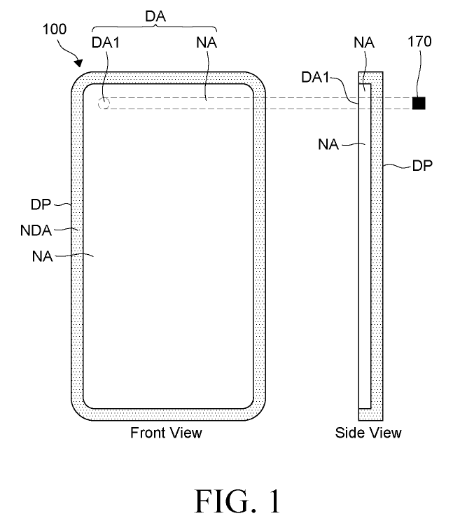

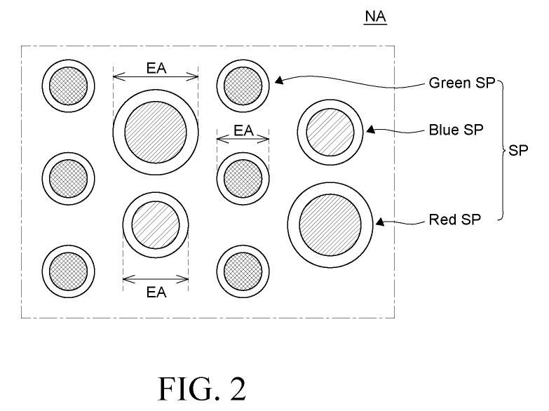

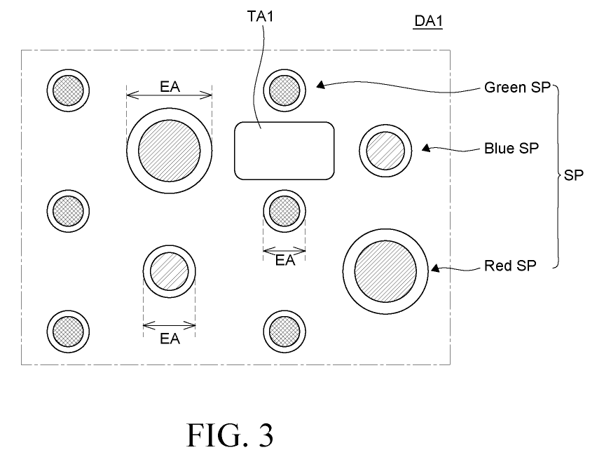

FIG. 1 is a schematic plan view of a display device according to an embodiment of the present disclosure. FIG. 2 is an enlarged plan view illustrating placement of sub-pixels in a normal area in a display device according to an example embodiment of the present disclosure. FIG. 3 is an enlarged plan view illustrating placement of sub-pixels in an optical area in a display device according to an embodiment of the present disclosure.

Referring to FIGS. 1 to 3, a display device 100 according to an example embodiment of the present disclosure can include a display panel DP displaying an image and one or more optical electronic devices 170.

The display panel DP is a panel for displaying images to a user. The display panel DP can include a display element for displaying an image, a driving element for driving the display element, and wiring lines for transmitting various signals to the display element and the driving element. The display panel DP can be an organic light emitting display panel. For example, the display element can be an organic light emitting element including an anode, an emission layer, and a cathode.

The optical electronic device 170 can be a device that receives light transmitted through the display panel DP and performs a predetermined function according to the received light. The optical electronic device 170 can include a light receiving device such as a camera or a sensor that receives light.

The optical electronic device 170 can be located on a rear surface of the display panel DP (a surface opposite to a surface on which an image is displayed). As described above, the optical electronic device 170 is a device requiring light reception, but can be located on the rear surface of the display panel DP. Accordingly, the optical electronic device 170 is not exposed to the front surface of the display device 100. Accordingly, when the user looks at the front surface of the display device 100, the optical electronic device 170 is not visible.

The display panel DP can include a display area DA and a non-display area NDA.

The display area DA is an area in which images are displayed in the display panel DP. In the display area DA, a plurality of sub-pixels constituting a plurality of pixels and a circuit for driving the plurality of sub-pixels can be disposed. The plurality of sub-pixels can be minimum units constituting the display area DA, and a display element can be disposed in each of the plurality of sub-pixels, and the plurality of sub-pixels can constitute a pixel. For example, an organic light emitting element including an anode, an emission layer, and a cathode can be disposed in each of the plurality of sub-pixels, but it is not limited thereto. Further, a circuit for driving the plurality of sub-pixels can include components such as a driving element and a wiring line. For example, the circuit can include a thin film transistor, a storage capacitor, a gate line, a data line, and the like, but is not limited thereto.

The non-display area NDA is an area where an image is not displayed. The non-display area NDA can be bent and not seen from a front surface, or can be covered by a case, or can be referred to as a bezel area.

FIG. 1 illustrates that the non-display area NDA has a rectangular frame shape surrounding the rectangular display area DA, but is not limited thereto. The shape and arrangement of the display area DA and the non-display area NDA are not limited to the example shown in FIG. 1. For example, the display area DA and the non-display area NDA can vary depending on the design of an electronic device equipped with the display device 100.

In the non-display area NDA, various wiring lines and circuits for driving the organic light emitting element of the display area DA can be disposed. For example, in the non-display area NDA, a link line which transmits signals to a plurality of sub-pixels and circuits of the display area DA, a gate in panel (GIP) line, or a driving IC, such as a gate driver IC or a data driver IC, can be disposed, but is not limited thereto.

The display area DA can include a normal area NA and at least one optical area DA1. For example, the display area DA can include a normal area NA and an optical area DA1. The normal area NA is an area other than the optical area DA1 in the display area DA. The normal area NA can be formed to surround the optical area DA1.

At least a portion of the optical area DA1 can overlap the optical electronic device 170.

In the display device 100 according to an example embodiment, even though the electronic optical device 170 is positioned to be hidden behind the display panel DP, the electronic optical device 170 should be able to receive light normally and perform a predetermined function normally.

Accordingly, the optical area DA1 must have both an image display structure and a light transmission structure. For example, since the optical area DA1 is a partial area of the display area DA, a sub-pixel for displaying an image must be disposed in the optical area DA1. In one or more optical areas DA1, a light transmission structure for transmitting light to one or more optical electronic devices 170 must be formed.

The normal area NA and the optical area DA1 included in the display area DA are areas in which image display is possible, but the normal area NA is an area in which a light transmission structure does not need to be formed, and the optical area DA1 is an area in which a light transmission structure needs to be formed. Accordingly, the optical area DA1 must have a transmittance at a predetermined level or higher, and the normal area NA may not have light transmittance or can have a low transmittance at a predetermined level or less.

As a method for increasing the transmittance of the optical area DA1, the pixel density of the optical area DA1 and the normal area NA can be designed differently. Therefore, the optical area DA1 and the normal area NA can have different resolutions, a sub-pixel arrangement structure, the number of sub-pixels per unit area, an electrode structure, a line structure, an electrode arrangement structure, or a line arrangement structure.

For example, the number of sub pixels per unit area in the optical area DA1 can be smaller than the number of sub pixels per unit area in the normal area NA. For example, the resolution of the optical area DA1 can be lower than the resolution of the normal area NA. At this time, the number of sub-pixels per unit area is a unit that measures the resolution, and can be referred to as Pixels Per Inch (PPI), which means the number of pixels in 1 inch.

As another example, in order to increase the transmittance of the optical area DA1, the pixel sizes of the optical area DA1 and the normal area NA can be formed differently. Specifically, the number of sub pixels per unit area of the optical area DA1 is the same as or similar to the number of sub pixels per unit area of the normal area NA, but the size (i.e., the size of the emission area) of each sub pixel disposed in the optical area DA1 can be formed to be smaller than the size (i.e., the size of the emission area) of each sub pixel disposed in the normal area NA.

Hereinafter, for convenience of description, an example will be described in which the pixel density of the optical area DA1 is formed to be smaller than the pixel density of the normal area NA in order to increase the transmittance of the optical area DA1.

Referring to FIGS. 2 and 3, a plurality of sub-pixels can be disposed in each of the normal area NA and the optical area DA1 included in the display area DA. For example, the plurality of sub-pixels can include a red sub-pixel Red SP that emits red light, a green sub-pixel Green SP that emits green light, and a blue sub-pixel Blue SP that emits blue light. Each of the plurality of sub pixels can include an emission area EA. In FIGS. 2 and 3, each sub-pixel is illustrated in a circular shape, but is not limited thereto. The shape and arrangement of the sub-pixels can vary as necessary.

Referring to FIG. 2, the normal area NA can include an emission area EA without including a light transmission structure. In contrast, the optical area DA1 should include not only the emission area EA, but also a light transmission structure. Accordingly, referring to FIG. 3, the optical area DA1 can include an emission area EA and a transmission area TA1.

The emission area EA and the transmission area TA1 can be distinguished depending on whether light can be transmitted. For example, the emission area EA can be an area in which light transmission is impossible, and the transmission area TA1 can be an area in which light transmission is possible.

In addition, the light-emitting area EA and the transmission area TA1 can be distinguished depending on whether a specific metal layer is formed. For example, in the transmission area TA1, components which reflect light to be transmitted to the optical electronic device 170, such as a touch line or a cathode, may not be disposed. In addition, in the transmission area TA1, components such as a bank or a black matrix that absorb light may not be disposed. However, the present disclosure is not limited thereto, and the light emitting layer or some organic/inorganic insulating layers may not be disposed depending on the design structure or to increase the amount of light received by the optical electronic device 170 in the transmission area TA1.

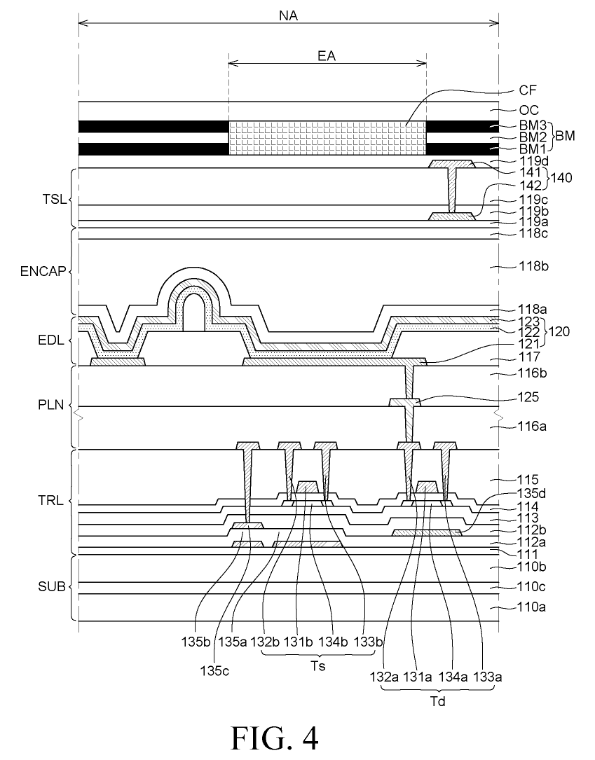

FIG. 4 is a cross-sectional view illustrating a cross-sectional structure of a partial pixel area disposed in a normal area in a display device according to an embodiment of the present disclosure.

Referring to FIG. 4, in the normal area NA, the transistor layer TRL can be disposed on the substrate SUB, and the planarization layer PLN can be disposed on the transistor layer TRL. Further, the light emitting element layer EDL can be disposed on the planarization layer PLN, the encapsulation layer ENCAP can be disposed on the light emitting element layer EDL, the touch sensing layer TSL can be disposed on the encapsulation layer ENCAP, and the protective layer 119d can be disposed on the touch sensing layer TSL. Further, a black matrix BM and a plurality of color filters CF can be disposed on the protection layer 119d.

The substrate SUB is a component for supporting various components included in the display device 100 and can be formed of an insulating material. The substrate SUB can include a first substrate 110a, a second substrate 110b, and an interlayer insulating film 110c. As described above, the substrate SUB is composed of the first substrate 110a, the second substrate 110b, and the interlayer insulating film 110c, thereby preventing the penetration of moisture. For example, the first substrate 110a and the second substrate 110b can be polyimide (PI) substrates. In another example, each of the first substrate 110a and the second substrate 110b may include glass or, plastic, a flexible polymer film, or the like. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer(COC), triacetylcellulose (TAC) film, polyvinyl alcohol (PVA) film, polyimide (PI) film, and polystyrene (PS), which is only an example and is not necessarily limited thereto.

In the transistor layer TRL, various patterns 131a, 132a, 133a, 134a, 131b, 132b, 133b, 134b, various insulation films 111, 112a, 112b, 113b, 114, and 115, and various metal patterns 135a, 135b, 135c, and 135d for forming transistors such as a driving transistor Td and at least one switching transistor Ts and at least one capacitor can be disposed.

A multi-buffer layer 111 can be disposed on the second substrate 110b, and a first metal layer 135a and a second metal layer 135b can be disposed on the multi-buffer layer 111. The first metal layer 135a can serve to block light and can be referred to as a light blocking layer. The first metal layer 135a can prevent the second active layer 134b of the switching transistor Ts formed of an oxide semiconductor from being damaged by light.

A first interlayer insulating film 112a can be disposed on the first metal layer 135a and the second metal layer 135b. The third metal layer 135c can be disposed on the first interlayer insulating film 112a so as to overlap the second metal layer 135b to implement the capacitor Cst. The third metal layer 135c of the capacitor Cst can be electrically connected to the second source electrode 132b or the second drain electrode 133b of the switching transistor Ts. However, the connection relationship of the capacitor Cst can be changed according to the pixel driving circuit without being limited thereto.

The second interlayer insulating film 112b can be disposed on the third metal layer 135c.

A fourth metal layer 135d can be disposed on the second interlayer insulating film 112b. The fourth metal layer 135d can serve to block light and can be referred to as a light shielding layer. The fourth metal layer 135d can prevent the first active layer 134a of the driving transistor Td formed of an oxide semiconductor from being damaged by light.

The active buffer layer 113 can be disposed on the fourth metal layer 135d, and the first active layer 134a of the driving transistor Td and the second active layer 134b of the switching transistor Ts can be disposed on the active buffer layer 113.

The first active layer 134a of the driving transistor Td can be disposed to overlap the fourth metal layer 135d with the active buffer layer 113 interposed therebetween.

The second active layer 134b of the switching transistor Ts can be disposed to overlap the first metal layer 135a with the first interlayer insulating film 112a, the second interlayer insulating film 112b, and the active buffer layer 113 therebetween.

For example, the first active layer 134a and the second active layer 134b can be independently formed of polycrystalline silicon, amorphous silicon, or oxide semiconductor, but are not limited thereto. For convenience of processing, the first active layer 134a and the second active layer 134b can be formed of the same material in the same process.

A gate insulating film 114 can be disposed on the first active layer 134a and the second active layer 134b.

The first gate electrode 131a of the driving transistor Td and the second gate electrode 131b of the switching transistor Ts can be disposed on the gate insulating film 114. The first gate electrode 131a of the driving transistor Td can be disposed to overlap the first active layer 134a with the gate insulating film 114 interposed therebetween, and the second gate electrode 131b of the switching transistor Ts can be disposed to overlap the second active layer 134b with the gate insulating film 114 interposed therebetween.

For example, the first gate electrode 131a and the second gate electrode 131b can each independently be a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but are not limited thereto. For convenience of processing, the first gate electrode 131a and the second gate electrode 131b can be formed of the same material in the same process.

A third interlayer insulating layer 115 can be disposed on the first gate electrode 131a and the second gate electrode 131b.

The first source electrode 132a and the first drain electrode 133a of the driving transistor Td and the second source electrode 132b and the second drain electrode 133b of the switching transistor Ts can be disposed on the third interlayer insulating film 115.

For example, the first source electrode 132a, the first drain electrode 133a, the second source electrode 132b, and the second drain electrode 133b can each independently be a single layer or multiple layers formed of magnesium (Mg), aluminum (Al), nickel (Ni), chromium (Cr), molybdenum (Mo), tungsten (W), gold (Au), or an alloy thereof, but are not limited thereto. For convenience of processing, the first source electrode 132a and the first drain electrode 133a, the second source electrode 132b, and the second drain electrode 133b can be simultaneously formed of the same material on the third interlayer insulating film 115.

The first source electrode 132a and the first drain electrode 133a can be connected to one side and the other side of the first active layer 134a, respectively, through contact holes provided in the gate insulating film 114 and the third interlayer insulating film 115. When the first active layer 134a is formed of an oxide semiconductor, one side and the other side of the first active layer 134a connected to the first source electrode 132a and the first drain electrode 133a can be doped with impurities to become conductive.

The second source electrode 132b and the second drain electrode 133b can be connected to one side and the other side of the second active layer 134b, respectively, through contact holes provided in the gate insulating film 114 and the third interlayer insulating film 115. When the second active layer 134b is formed of an oxide semiconductor, one side and the other side of the second active layer 134b connected to the second source electrode 132b and the second drain electrode 133b can be doped with impurities to become conductive.

The first planarization layer 116a can be disposed on the first source electrode 132a, the first drain electrode 133a, the second source electrode 132b, and the second drain electrode 133b. The first planarization layer 116a protects the driving transistor Td and the switching transistor Ts and planarizes an upper portion thereof.

The connection electrode 125 can be disposed on the first planarization layer 116a. The connection electrode 125 can be connected to one of the first source electrode 132a and the first drain electrode 133a through a contact hole provided in the first planarization layer 116a. For example, the first drain electrode 133a can be connected to the connection electrode 125.

The second planarization layer 116b can be disposed on the connection electrode 125.

The light emitting element layer EDL can be disposed on the second planarization layer 116b. The light-emitting element layer EDL can include the light-emitting element 120 including the anode 121, the light-emitting layer 122, and the cathode 123. The light-emitting element 120 can be disposed to correspond to each of the plurality of sub-pixels.

The anode 121 can be disposed on the second planarization layer 116b. The anode 121 can be electrically connected to the connection electrode 125 through a contact hole provided in the second planarization layer 116b. The anode 121 can be formed of a transparent conductive oxide. For example, the anode 121 can be formed of a transparent conductive oxide such as ITO or IZO, but is not limited thereto. In the case of a top emission type in which light emitted from the light emitting element 120 is emitted to the top of the display device 100, the anode 121 can further include a reflective layer to allow the light to travel upward.

A bank 117 can be disposed on the second planarization layer 116b so as to expose at least a part of the anode 121. The bank 117 can be disposed to cover an end of the anode 121 and open a portion corresponding to the emission area of the sub-pixel.

The bank 117 can be made of an inorganic insulating material, such as silicon nitride (SiNx) or silicon oxide (SiOx), or an organic insulating material, such as benzocyclobutene-based resin, acrylic resin, or imide-based resin, and can be formed as a single layer or multiple layers, but is not limited thereto. The bank 117 can include a dye formed of a black resin or capable of absorbing light to prevent color mixture between sub-pixels.

A spacer can be further disposed on the bank 117, and the spacer can be formed of the same material as the bank 117.

The light emitting layer 122 can be disposed on the anode 121. The light emitting layer 122 is not separated for each of the plurality of sub pixels and can be formed as a common layer, but is not limited thereto. The emission layer 122 can be disposed on the anode 121 so as to correspond to an emission area of each of the plurality of sub-pixels. The light-emitting element 120 can further include a plurality of organic films other than the light-emitting layer 122.

The cathode 123 can be disposed on the light emitting layer 122.

The encapsulation layer ENCAP can be disposed on the light emitting element layer EDL. The encapsulation layer ENCAP can have a single-layer structure or a multi-layer structure. For example, the encapsulation layer ENCAP can include a first encapsulation layer 118a, a second encapsulation layer 118b, and a third encapsulation layer 118c.

In this case, the first encapsulation layer 118a and the third encapsulation layer 118c can be inorganic films, and the second encapsulation layer 118b can be an organic film. The second encapsulation layer 118b, which is an organic film, can be applied thickly, such that the upper portion of the light-emitting element 120 can be planarized, impact can be easily absorbed, and foreign matter introduced during the process can be covered.

A touch sensing layer TSL can be disposed on the encapsulation layer ENCAP.

A first touch buffer film 119a can be disposed on the encapsulation layer ENCAP. The first touch buffer film 119a prevents damage to the light emitting element 120 during a process of forming the touch sensing layer TSL.

The touch line 140 can be disposed on the first touch buffer film 119a. The touch line 140 can be disposed to overlap the bank 117 so as not to reduce the light emission efficiency of light emitted from the light emitting element 120.

The touch line 140 can include a touch sensor metal 141 and a bridge metal 142 positioned on different layers.

The second touch buffer film 119b and the organic insulating layer 119c can be disposed between the bridge metal 142 and the touch sensor metal 141. The bridge metal 142 can be disposed on the first touch buffer film 119a. The second touch buffer film 119b and the organic insulating layer 119c can be disposed on the bridge metal 142. The second touch buffer film 119b insulates the bridge metal 142 and the touch sensor metal 141 from each other and insulates the bridge metals 142 disposed adjacent to each other. The organic insulating layer 119c is formed of an organic material to provide a flat surface, and has relatively excellent buffering properties, thereby preventing damage to the touch sensing layer TSL. The touch sensor metal 141 can be disposed on the organic insulating layer 119c. The touch sensor metal 141 can be electrically connected to the bridge metal 142 through contact holes formed in the second touch buffer film 119b and the organic insulating layer 119c.

A protective layer 119d can be disposed on the touch sensing layer TSL. The protective layer 119d can be disposed to cover the touch line 140. The protective layer 119d can be formed of an organic insulating material. The protective layer 119d prevents damage to the touch sensing layer TSL during a process of forming the color filter CF and the black matrix BM. In addition, the protective layer 119d planarizes the upper portion of the touch sensing layer TSL.

A plurality of color filters CF and a black matrix BM are disposed on the protective layer 119d.

The plurality of color filters CF and the black matrix BM suppress reflection of external light. Light introduced from the outside can be reflected by a touch line 140 formed of a metal having high reflectivity, an anode 121 of the light-emitting element 120, or a component formed of a metal disposed below the light-emitting element 120. The visibility of an image displayed on the display device 100 can be deteriorated by the reflected light.

The color filter CF and the black matrix BM prevent external light from being transmitted into the display device 100 and allow light emitted from the light emitting element 120 to be well transmitted to the outside of the display device 100.

Each of the plurality of color filters CF can be disposed on the protection layer 119d to correspond to each of the plurality of sub pixels. The plurality of color filters CF can include a red color filter, a green color filter, and a blue color filter. The red color filter can be disposed to correspond to a red sub-pixel, the green color filter can be disposed to correspond to a green sub-pixel, and the blue color filter can be disposed to correspond to a blue sub-pixel. At least a part of each of the plurality of color filters CF can overlap at least a part of the black matrix BM.

The conventional polarizing plate is not separated for each of the plurality of sub pixels but is formed as a common layer. Since the transmittance is formed to be about 45% or less, the reflectance is low, but there is a problem in that the luminance is deteriorated.

The color filter CF is disposed to correspond to each of the plurality of sub-pixels and is formed with a color corresponding to the color of each sub-pixel. Accordingly, when the color filter CF and the black matrix BM are provided, the transmittance is about 40% to 70%, which is higher than that of the polarizing plate. Accordingly, light emitted from the light emitting element 120 disposed in each sub pixel is well transmitted, but external light can be easily absorbed. Therefore, the power consumption can be reduced, the lifespan can be improved, and the thickness of the display device including the polarizing plate can be thinner.

The black matrix BM can be disposed on the protective layer 119d so as to partition the plurality of color filters CF from each other. Accordingly, the black matrix BM prevents color mixture of light emitted from each of adjacent sub pixels.

The black matrix BM can be disposed at a position corresponding to the bank 117.

A width of the black matrix BM can be different from a width of the bank 117. For example, the width of the black matrix BM can be formed to be narrower than the width of the bank 117. Accordingly, the opening width of the black matrix BM is formed to be wider than the width of the opening of the bank 117. In this case, a pull back structure is formed in which the end of the black matrix BM is positioned further back than the end of the bank 117. This pull-back structure can provide a wide viewing angle. For example, when the distance between the end of the bank 117 and the end of the corresponding black matrix BM is 4.3 um, a viewing angle of 30° based on 60% of luminance can be secured. And when the distance between the end of the bank 117 and the end of the corresponding black matrix BM is 6.4 um, a viewing angle of 45° based on 60% of luminance can be secured, and when the distance is 8.4 um, a viewing angle of 60° based on 60% of luminance can be secured.

The black matrix BM can be disposed at a position overlapping the touch line 140. The width of the black matrix BM can be formed to be different from the width of the touch line 140. A width of the touch line 140 can be formed to be narrower than a width of the black matrix BM so that the touch line 140 formed of a metal having high reflectivity is not exposed.

Accordingly, in the display device according to the present embodiment, the black matrix BM can have a triple-layered structure composed of a first layer BM1, a second layer BM2, and a third layer BM3 sequentially stacked. Each layer of the black matrix BM will be described later.

An overcoating layer OC can be disposed on the plurality of color filters CF and the black matrix BM. The overcoating layer OC covers the plurality of color filters CF and the black matrix BM to planarize the upper surface. The overcoating layer OC can be formed of an organic material having excellent flatness and optically transparent.

A cover member can be bonded onto the overcoating layer OC.

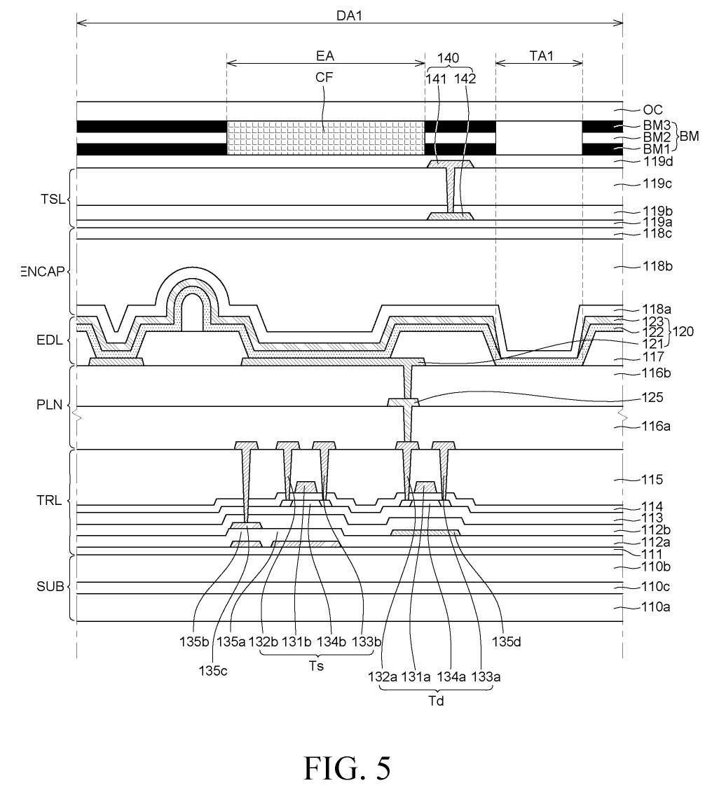

Hereinafter, the optical area DA1 of the display device 100 will be described in more detail with reference to FIG. 5. FIG. 5 is a cross-sectional view illustrating a cross-sectional structure of some sub-pixels disposed in an optical area in a display device according to an embodiment of the present disclosure.

The optical area DA1 is an area in which one or more optical electronic devices 170 are disposed. Accordingly, the optical area DA1 overlaps one or more optical electronic devices 170. The optical area DA1 can transmit light required for the operation of the optical electronic device 170 while displaying an image. Accordingly, the optical area DA1 includes an emission area EA and a transmission area TA1.

The light-emitting area EA and the transmission area TA1 of the optical area DA1 can include a substrate SUB, a transistor layer TRL, a planarization layer PNL, a light-emitting element layer EDL, an encapsulation layer ENCAP, a touch sensor layer TSL, a protective layer 119d, a color filter CF, a black matrix BM, and an overcoating layer OC.

The substrate SUB, the transistor layer TRL, the planarization layer PLN, the light emitting element layer EDL, the encapsulation layer ENCAP, the touch sensor layer TSL, the protective layer 119d, the color filter CF, the black matrix BM, and the overcoating layer OC included in the optical area DA1 are substantially identical to components having the same reference numerals disposed in the normal area NA of the display panel DP, and therefore, redundant descriptions thereof will be omitted.

The optical electronic device 170 can be disposed on the rear surface of the plate SUB in the optical area DA1. As described above, the optical electronic device 170 can include a light receiving device such as a camera or a sensor that receives light.

In the optical area DA1, the emission area EA is substantially the same as the structure of the normal area NA of the display panel DP, except that the touch line 140 is not disposed, so that a redundant description will be omitted.

Hereinafter, the transmission area TA1 disposed in the optical area DA1 will be described.

The substrate SUB and various types of insulation films 111, 112a, 112b, 113, 114, 115, 116a, 116b, 118a, 118b, 118c, 119a, 119b, 119c, 119d, and OC disposed in the emission area EA of the optical area DA1 can be equally disposed in the transmission area TA1 of the optical area DA1.

However, in addition to the insulating material disposed in the emission area EA of the optical area DA1, some of the material layers having electrical or opaque properties may not be disposed in the transmission area TA1 of the optical area DA1.

According to an embodiment of the present disclosure, a metal material layer 135a, 135b, 135c, 135d, 131a, 132a, 133a, 131b, 132b, 133b, and 133b and a semiconductor layer 134a, 134b are not disposed in the transmission area TA1. In addition, the anode 121 included in the light-emitting element 120 may not be disposed in the transmission area TA1. In addition, the touch line 140 may not be disposed in the transmission area TA1. In addition, in order to secure the transmittance of the transmission area TA1, the cathode 123 may not be disposed in the transmission area TA1.

Since the transmission area TA1 of the optical area DA overlaps the optical electronic device 170, an opaque component such as a metal electrode is not disposed in the transmission area TA1 for a normal operation of the optical electronic device 170, thereby increasing the transmittance of the transmission area TA1.

In addition, in order to increase the transmittance of the transmission area TA, the color filter CF may not be disposed in the transmission area TA1.

Hereinafter, a black matrix BM having a triple-layered structure will be described in detail with reference to FIGS. 4 and 5.

In the normal area NA and the optical area DA1, the black matrix BM can have a triple-layered structure composed of a first layer BM1, a second layer BM2, and a third layer BM3 sequentially stacked.

A refractive index of each of the first layer BM1 and the third layer BM3 can be smaller than a refractive index of the second layer BM2. For example, the first layer BM1 and the third layer BM3 can be low refractive layers, and the second layer BM2 can be high refractive layers.

The first layer BM1 and the third layer BM3, which are low refractive layers, serve to shield external light from transmitting inside the display panel.

As the second layer BM2, which is a high refractive layer, is disposed between the first layer BM1 and the third layer BM3 which are low refractive layers, external light can be effectively blocked by refractive index matching and some external light or unnecessary internal reflected light introduced into the display panel can be prevented from being visually recognized by the user. Accordingly, reflectance is low, and the lower touch line 140 is not visually recognized through display device 100, so that a display device having excellent display quality can be provided.

The first layer BM1 and the third layer BM3 can be a black matrix layer including a black material, and the second layer BM2 can be a red matrix layer, a blue matrix layer, or a white matrix layer. In this case, due to the difference in refractive index for each layer, external light is absorbed and some external light or unnecessary internal reflected light introduced into the display panel is prevented from being visually recognized. Preferably, the second layer BM2 can be a white matrix layer. In this case, a difference in refractive index between each of the first layer BM1 and the third layer BM3, which are black matrix layers, and the second layer BM2, which is a white matrix layer, is large, which is more advantageous in lowering reflectance, and it is possible to solve the problem in which the lower touch line 140 is visually recognized.

The optical density OD of the third layer BM3 of the black matrix BM can be formed to be higher than the optical density of the first layer BM1. Optical density (OD) is a physical property of the specimen indicating the degree of light absorption. Among the first layer BM1, the second layer BM2, and the third layer BM3 of the black matrix BM, the third layer BM3 is positioned closest to the display surface. Accordingly, in order to maximize the external light absorption rate, the optical density of the third layer BM3 can be higher than that of the first layer BM1.

For example, the optical density (unit length 1 um) of the third layer BM3 can be 1 to 2, and the optical density (unit length 1 um) of the first layer BM1 can be 1 or less. In this case, while the external light absorption rate is excellent, the lower touch line 140 may not be visually recognized.

Each of the first layer BM1 and the third layer BM3 which is a black matrix layer can include an inorganic black material. For example, the inorganic black material can be carbon black, but is not limited thereto. The inorganic black material greatly increases the absorption rate of external light by increasing the optical density.

In order to form an optical density of the third layer BM3 higher than that of the first layer BM1, a weight ratio of the inorganic black material included in the third layer BM3 can be higher than a weight ratio of the inorganic black material included in the first layer BM1.

If necessary, the first layer BM1 can be formed to include any one of organic black materials, such as aniline black, lactam black, and perylene black, rather than an inorganic black material. When such an organic black material is used, an optical density is lower than that of the inorganic black material. Therefore, when the third layer BM3 includes an inorganic black material and the first layer BM1 includes an organic black material, an optical density of the third layer BM3 can be formed to be higher than that of the first layer BM1.

When the second layer BM2 is a red matrix layer, a red dye can be included, and when the second layer BM2 is a blue matrix layer, a blue dye can be included.

Preferably, the second layer BM2 can be a white matrix layer. When the second layer BM2 is a white matrix layer, white nanoparticles can be included. For example, the white nanoparticles can be titanium dioxide (TiO₂), but are not limited thereto. Specifically, for example, the white nanoparticles can be titanium dioxide of one or more of rutile titanium dioxide and anatase titanium dioxide. In addition, the shape of the titanium dioxide can include at least one selected from a spherical, hollow, and core-shell structure, but is not limited thereto. These white nanoparticles have a high refractive index. Accordingly, a difference in refractive index between the first layer BM1 and the second layer BM2, and a difference in refractive index between the third layer BM3 and the second layer BM2 is maximized to further reduce reflectance and further suppress visually recognizing the lower touch line 140.

For example, a refractive index of the first layer BM1 of the black matrix BM can be 1.6 to 1.7, a refractive index of the second layer BM2 can be 2.0 to 2.5, and a refractive index of the third layer BM3 can be 1.5 to 1.6. When the refractive indices of the first layer BM1, the second layer BM2, and the third layer BM3 of the black matrix BM are adjusted as described above, the incidence of external light can be minimized, the internal reflected light may not be visually recognized, and the visibility of the lower touch line 140 can be minimized. Accordingly, the display device 100 having excellent display quality can be provided.

According to the present embodiment, the widths of the first layer BM1, the second layer BM2, and the third layer BM3 of the black matrix BM can all be the same. However, the present disclosure is not limited thereto.

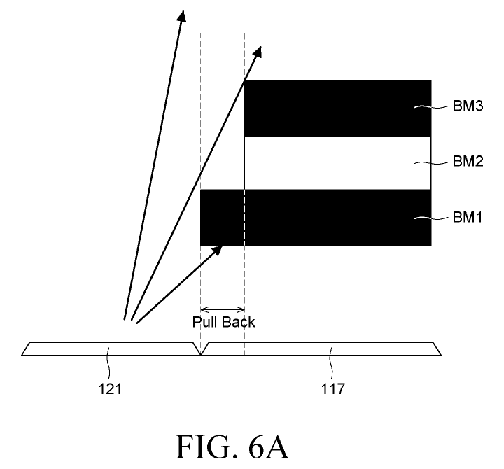

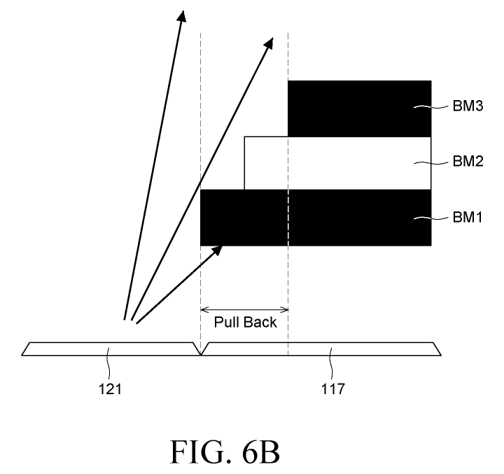

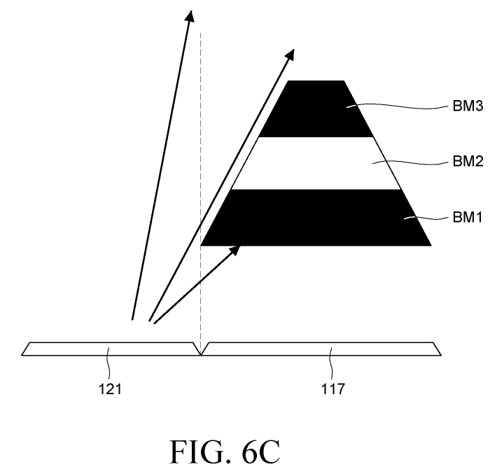

FIGS. 6A to 6C are schematic diagrams illustrating various examples of the structures of a black matrix, which can be used in each display device according to examples of the present disclosure. Hereinafter, various structures of the black matrix BM will be described with reference to FIGS. 6A to 6C. In FIGS. 6A to 6C, for convenience of description, the remaining components are not illustrated except for the black matrix BM, the anode 121, and the bank 117.

Referring to an example in FIG. 6A, a width of the first layer BM1 of the black matrix BM can be greater than a width of the second layer BM2 and a width of the third layer BM3. Further, a width of the second layer BM2 and a width of the third layer BM3 can be the same.

The end of the first layer BM1 can be formed to match the end of the corresponding bank 117. Accordingly, the first layer BM1 can be formed without a pull back.

Each of the width of the second layer BM2 and the width of the third layer BM3 can be formed to be smaller than the width of the first layer BM1, such that ends of the second layer BM2 and the third layer BM3 can be located outside more than the ends of the corresponding bank 117. Accordingly, ends of the second layer BM2 and the third layer BM3 can be formed in a pull-back structure that is further rearward than the end of the bank 117.

In this case, an area capable of absorbing external light is increased by the first layer BM1 formed without a pull back, which can be advantageous in reducing reflectance.

However, it can be applied to a device in which some light is blocked by the first layer BM1 formed without a pullback and a wide viewing angle is not required.

Referring to FIG. 6B, in another embodiment, the first layer BM1 of the black matrix BM can be formed to have a wide width without a pull back, the second layer BM2 can be formed to have a width narrower than the first layer BM1, and the third layer BM3 can be formed to have a width narrower than the second layer BM2. Accordingly, the black matrix BM can be formed in a step shape.

In this case, the area of the third layer BM3 is reduced compared to the black matrix illustrated in FIG. 6A, which can be disadvantageous in absorbing external light. However, the width of the third layer BM3 is formed to be narrower than that of the black matrix shown in FIG. 6A, which can be advantageous in securing a viewing angle.

Referring to FIG. 6C, in another embodiment, the first layer BM1 of the black matrix BM can be formed to have a wide width without a pull back, the second layer BM2 can be formed to have a width narrower than the first layer BM1, and the third layer BM3 can be formed to have a width narrower than the second layer BM2. In this case, side surfaces of the first layer BM1, the second layer BM2, and the third layer BM3 can be formed with an inclined structure having the same inclination.

Accordingly, the black matrix BM can be formed in a trapezoidal shape or a pyramid shape with a truncated top. Other shapes/configurations may be possible.

The black matrix BM having such a structure can be advantageous in securing a wide luminance viewing angle. In addition, the inclination of each side surface of the first layer BM1, the second layer BM2, and the third layer BM3 can be adjusted according to the desired viewing angle.

As described above, in the CoE structure of the related art, there can be a problem in that the touch line disposed under the black matrix is visually recognized, thereby deteriorating the display quality. In clear contrast, in the black matrix BM according to an example embodiment of the present disclosure, a black matrix BM having a triple-layered structure including a first layer BM1 and a third layer BM3 of low refractive index and a second layer BM2 of high refractive index disposed between the first layer BM1 and the third layer BM3 of low refractive index can improve display quality because the touch line 140 is not visually recognized while lowering reflectance.

For example, when a single-layer black matrix and a color filter are formed on a glass substrate as in the prior art, reflectance can be 4.70%, and when a single-layer black matrix and a color filter are formed on a panel, reflectance can be 7.70%. Further, when a black matrix layer and a red matrix layer are laminated on a glass substrate to form a black matrix and a color filter having a double layer structure, reflectance can be 6.40%, and when a black matrix and a color filter having such a structure are formed on a panel, reflectance can be 8.2%. In this way, when the layer disposed on the outermost layer is a red matrix layer, it can be seen that the reflectance is higher than when a single layer of black matrix is formed due to a decrease in the absorption rate of external light.

Meanwhile, as in the example embodiment of the present disclosure, when a black matrix and a color filter having a triple-layered structure in which a black matrix layer, a white matrix layer, and a black matrix layer are stacked on a glass substrate, reflectance is as low as 3.75%. In addition, when the black matrix and the color filter having such a triple-layered structure are formed on the display panel, the reflectance is 5.8%, which is lower than when a single-layered black matrix or a black matrix layer and a red matrix layer are stacked in the prior art.

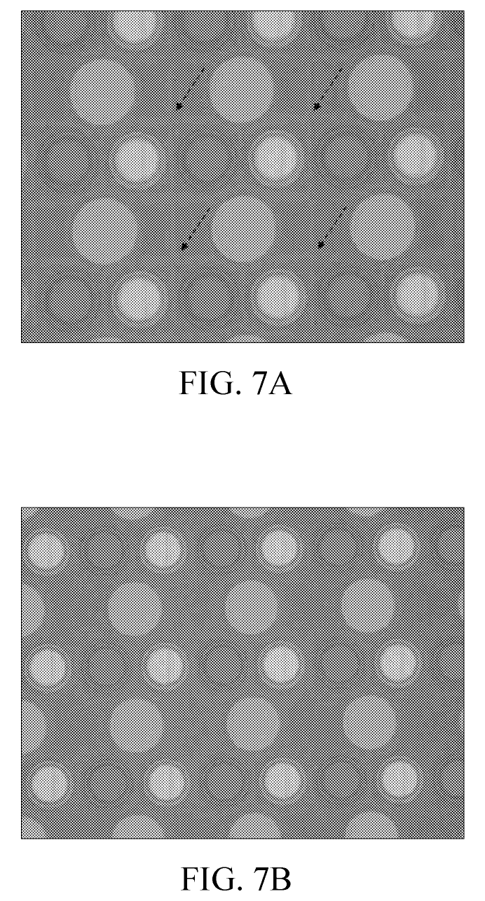

FIG. 7A is a sub-pixel photograph of a conventional display device including a single-layer black matrix, and FIG. 7B is a sub-pixel photograph of a display device including a triple-layer black matrix according to an example embodiment of the present disclosure.

Referring to FIG. 7A, when a single-layer black matrix is provided, it can be seen that the touch electrode under the black matrix is visually recognized.

In contrast, referring to FIG. 7B, according to an embodiment of the present disclosure, when a triple-layered black matrix in which a white matrix layer is stacked is formed between two black matrix layers, it can be seen that the lower touch electrode is not visually recognized.

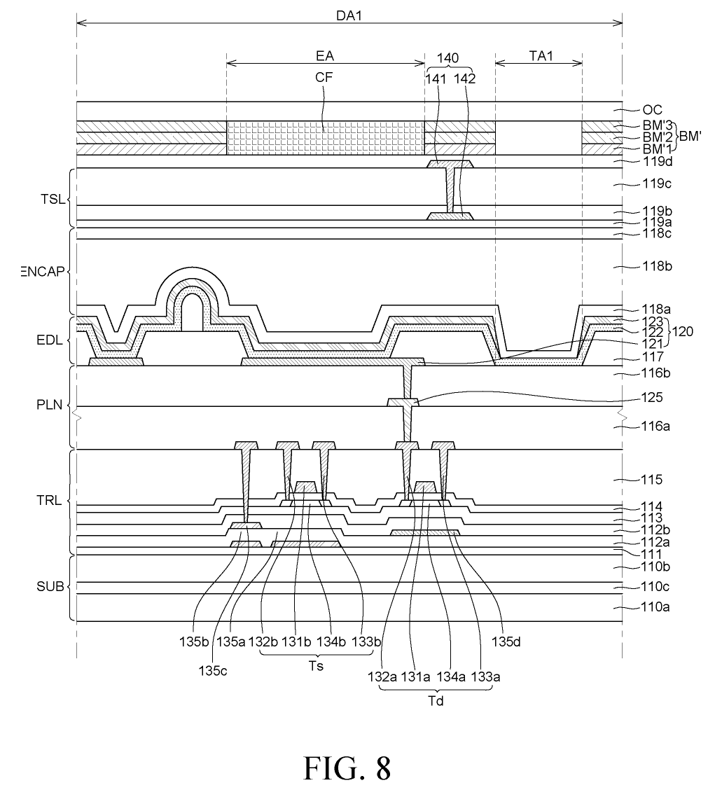

FIG. 8 is a cross-sectional view illustrating a cross-sectional structure of some sub-pixels disposed in an optical area in a display device according to another embodiment of the present disclosure. The display device illustrated in FIG. 8 has substantially the same configuration as the display device described with reference to FIGS. 1 to 6C and 7B except for a black matrix disposed in an optical area. Therefore, a redundant description of the same reference numerals will be omitted or may be briefly provided.

Referring to FIG. 8, the optical electronic device 270 can be disposed in the optical area DA1 of the display device. The optical electronic device 270 can include a light receiving device such as a camera or a sensor that receives light. For example, the electronic optical device 270 can be a detection sensor such as a proximity sensor or an illuminance sensor. Hereinafter, an example that the optical electronic device 270 is an infrared sensor that senses infrared rays will be described.

The optical electronic device 270 can be disposed below the substrate SUB in the optical area DA1. When the optical electronic device 270 is an infrared sensor, it should be received by an infrared sensor disposed on the rear surface of the substrate SUB after transmitting as many infrared rays as possible. Accordingly, the optical area DA requires higher infrared transmittance than the normal area NA. At the same time, it is necessary to minimize light incident from the outside to prevent deterioration of visibility due to reflected light.

Accordingly, in the optical area DA1, it can be advantageous that the black matrix BM′ transmits light in an infrared wavelength band well and blocks light in a visible light wavelength band incident from the outside.

In the optical area DA1, the black matrix BM′ can have a triple-layered structure in which a first layer BM′1, a second layer BM′2, and a third layer BM′3 are sequentially stacked.

In this case, the first layer BM'1 can be a long-wavelength visible ray blocking layer, the second layer BM'2 can be a short-wavelength visible ray blocking layer, and the third layer BM'3 can be an infrared transmitting layer that transmits light having an infrared wavelength.

For example, the first layer BM'1 includes a dye having a maximum absorption of 550 nm to 780 nm to block a long wavelength of visible light, but is not limited thereto. For example, the second layer BM'2 includes a dye having a maximum absorption of 380 nm to 550 nm to block a short wavelength of visible light, but is not limited thereto. For example, the third layer BM′3 can transmit infrared rays in a wavelength range of 940 nm to 1200 nm, but is not limited thereto.

The third layer BM′3 is positioned closest to the display surface to block some of the visible light while well transmitting infrared rays in the optical area DA1, thereby preventing deterioration in visibility due to the reflected light.

The second layer BM'2 disposed below the third layer BM'3 absorbs visible light of a short wavelength, and the first layer BM'1 absorbs visible light of a long wavelength. Accordingly, the first layer BM'1 and the second layer BM'2 can be block visible light that is not blocked from the third layer BM'3 and transmit infrared rays transmitted from third layer BM’3.

The triple-layered black matrix BM′ having the above configuration transmits light having an infrared wavelength well from the front surface of the optical area DA1 to improve the amount of infrared light received by the optical electronic device 270 disposed on the rear surface of the substrate SUB. At the same time, visible light incident from the outside is blocked to prevent the visibility from being degraded by the reflected light and the metal under the black matrix BM′ may not be visible.

The first layer BM'1 can be a layer including one or more dyes selected from a blue dye and a violet dye. These dyes absorb visible light of a long wavelength not absorbed in the third layer BM'3 to prevent deterioration in visibility due to reflection of external light and transmit infrared light to maintain a high amount of infrared light.

The second layer BM'2 can be a layer comprising one or more dyes selected from yellow dyes and orange dyes. These dyes absorb visible light of a short wavelength that is not absorbed by the third layer BM'3. Accordingly, it is possible to minimize the deterioration of visibility due to reflected light generated by external light. In addition, the amount of infrared light received can be maintained high by transmitting infrared rays.

The third layer BM′3 can be a layer including an organic black material. Organic black materials have lower optical density than inorganic black materials. Accordingly, while blocking visible light incident from the outside, infrared rays are transmitted to secure the amount of light required by the optical electronic device 270.

For example, the organic black material can be one or more selected from aniline black, lactam black, and perylene black.

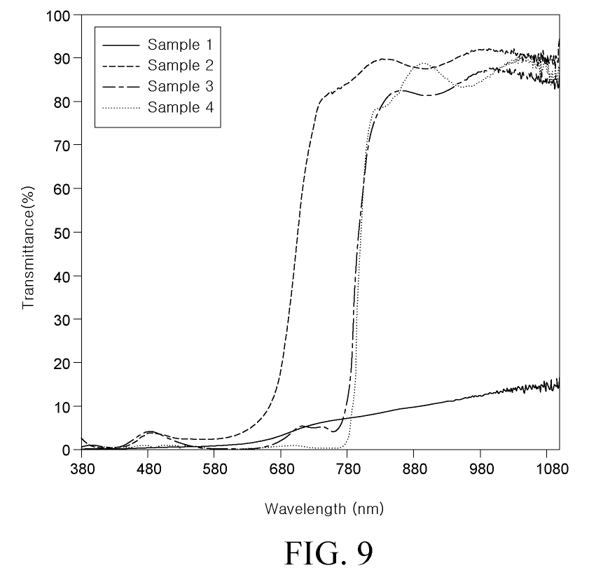

FIG. 9 is a graph showing a transmittance according to the configuration of a black matrix. Referring to FIG. 9, Sample 1 is a single-layer black matrix formed of an inorganic black material. In the case of Sample 1, the transmittance is very low in the visible light wavelength band, while the transmittance tends to increase in the wavelength band of 780 nm or more, but it can be seen that the transmittance is as low as 15% or less in the infrared wavelength band. Specifically, in Sample 1, which is composed of a single layer of inorganic black material, it was confirmed that the transmittance in the visible light wavelength band was 2.3%, and the transmittance in the infrared wavelength band was 15.9%.

In FIG. 9, Sample 2 is a single-layer black matrix formed of an organic black material. In the case of Sample 2, although the transmittance to visible light is higher than that of the inorganic black material, the transmittance to visible light of 600 nm or less is not high at 5% or less, and the transmittance in the infrared wavelength band of 940 nm to 1200 nm is 90%, indicating that the infrared transmittance is quite high. Specifically, it was confirmed that the infrared transmittance of Sample 2 was 89.5%, and the visible light transmittance was 18.7%.

In FIG. 9, Sample 3 is a black matrix having a double-layered structure composed of a second layer formed of an organic black material and a first layer formed including yellow or orange dyes. In the case of Sample 3, it can be seen that the transmittance in the visible light wavelength band is lower than that of Sample 2. In particular, it can be seen that the transmittance of visible light of 500 nm to 680 nm is close to 0, and the transmittance of visible light of 680 nm to 780 nm is also lower than that of Sample 2. In addition, it can be seen that the transmittance in the infrared wavelength band of 940 nm to 1200 nm is approximately 85% level, which is slightly lower than that of Sample 2. Specifically, it was confirmed that the infrared transmittance of Sample 3 was 83.3%, and the visible light transmittance was 2.1%.

In FIG. 9, Sample 4 is a black matrix having a triple-layered structure composed of a first layer formed including a violet or blue dye, a second layer formed including a yellow or orange dye, and a third layer formed of an organic black material.

In the case of Sample 3 described above, it can be seen that light is transmitted in some visible light wavelength ranges of 480 nm and 680 nm to 780 nm. In contrast, in the case of Sample 4 having a triple-layered structure, it can be seen that the light transmittance is less than 1% in the entire visible light range of 380 nm to 780 nm. On the other hand, it can be seen that the transmittance is very high at 90% in the infrared wavelength range of 940 nm to 1200 nm. Specifically, it was confirmed that the infrared transmittance of Sample 4 was 92.5%, and the visible light transmittance was 0.68%.

From this, the black matrix of the triple-layered structure, such as Sample 4, hardly transmits visible light, and has a very high infrared transmittance so that when formed in the optical area, it absorbs external light and suppresses deterioration of visibility due to reflected light while transmitting infrared light at a high level, thereby providing the amount of infrared light required by the optical electronic device (270).

The example embodiments of the present disclosure can also be described as follows:

According to an aspect of the present disclosure, a display device includes a substrate including a display area in which a plurality of sub pixels is disposed, a light emitting element disposed on the substrate so as to correspond to each of the plurality of sub pixels, an encapsulation layer disposed on the light emitting element, a touch sensing layer disposed on the encapsulation layer and including a plurality of touch electrodes, a plurality of color filters disposed on the touch sensing layer so as to correspond to each of the plurality of sub pixels, and a black matrix disposed on the touch sensing layer so as to partition the plurality of color filters from each other and having a triple-layered structure in which a first layer, a second layer, and a third layer are sequentially stacked. The display area includes an optical area through which light is transmitted and a normal area surrounding the optical area, and in the normal area, a refractive index of each of a first layer and a third layer of the black matrix is smaller than a refractive index of a second layer.

According to another feature of the present disclosure, in the normal area, each of the first layer and the third layer of the black matrix can be a black matrix layer, and the second layer can be a red matrix layer, a blue matrix layer, or a white matrix layer.

According to another feature of the present disclosure, the optical density of the third layer of the black matrix in the normal area can be higher than the optical density of the first layer.

According to another feature of the present disclosure, in the normal area, each of the first layer and the third layer of the black matrix can include an inorganic black material, and a weight ratio of the inorganic black material included in the third layer can be higher than a weight ratio of the inorganic black material included in the first layer.

According to another feature of the present disclosure, in the normal area, the second layer of the black matrix can include white nanoparticles, and the white nanoparticles can include titanium dioxide (TiO₂).

According to another feature of the present disclosure, in the normal area, the refractive index of the first layer of the black matrix can be 1.6 to 1.7, the refractive index of the second layer can be 2.0 to 2.5, and the refractive index of the third layer can be 1.5 to 1.6.

According to another feature of the present disclosure, in the normal area, the width of the first layer, the width of the second layer, and the width of the third layer of the black matrix can be the same each other.

According to another feature of the present disclosure, in the normal area, the width of the first layer of the black matrix can be greater than the width of the second layer and the width of the third layer.

According to another feature of the present disclosure, the width of the second layer and the width of the third layer can be the same each other.

According to another feature of the present disclosure, the width of the second layer can be larger than the width of the third layer.

According to another feature of the present disclosure, the black matrix can have a step shape.

According to another feature of the present disclosure, side surfaces of each of the first layer, the second layer, and the third layer can have an inclined structure having the same inclination, and the black matrix can have a trapezoidal shape.

According to another feature of the present disclosure, the optical area can include an optical electronic device that receives light transmitted through the substrate below the substrate and operates.

According to another feature of the present disclosure, in the optical area, the first layer of the black matrix can be a long wavelength visible ray blocking layer, the second layer can be a short wavelength visible ray blocking layer, and the third layer can be a layer that transmits light having an infrared wavelength.

According to another feature of the present disclosure, in the optical area, the first layer can comprise one or more selected from a blue dye and a violet dye, the second layer can comprise one or more selected from a yellow dye and an orange dye, and the third layer can comprise an organic black material.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a display area in which a plurality of sub pixels is disposed;
a light emitting element disposed on the substrate so as to correspond to each of the plurality of sub pixels;
an encapsulation layer disposed on the light emitting element;
a touch sensing layer disposed on the encapsulation layer and including a plurality of touch metals;
a plurality of color filters disposed on the touch sensing layer so as to correspond to each of the plurality of sub pixels; and
a black matrix disposed on the touch sensing layer so as to partition the plurality of color filters from each other, the black matrix having a triple-layered structure in which a first layer, a second layer, and a third layer are stacked,
wherein the display area includes an optical area through which light is transmitted and a normal area which encloses the optical area, and
wherein in the normal area, a refractive index of each of at least one of the first layer and the third layer of the black matrix is smaller than a refractive index of the second layer of the black matrix.

2. The display device according to claim 1, wherein in the normal area, each of the first layer and the third layer of the black matrix is a black matrix layer, and
the second layer of the black matrix is a red matrix layer, a blue matrix layer, or a white matrix layer.

3. The display device according to claim 1, wherein an optical density of the third layer of the black matrix in the normal area is higher than an optical density of the first layer of the black matrix.

4. The display device according to claim 1, wherein each of the first layer and the third layer of the black matrix in the normal area includes an inorganic black material.

5. The display device according to claim 4, wherein a weight ratio of the inorganic black material included in the third layer is higher than a weight ratio of the inorganic black material included in the first layer.

6. The display device according to claim 1, wherein in the normal area, the second layer of the black matrix comprises white nanoparticles.

7. The display device according to claim 6, wherein the white nanoparticles comprise titanium dioxide (TiO₂).

8. The display device according to claim 1, wherein in the normal area, a refractive index of the first layer of the black matrix is 1.6 to 1.7, a refractive index of the second layer of the black matrix is 2.0 to 2.5, and a refractive index of the third layer of the black matrix is 1.5 to 1.6.

9. The display device according to claim 1, wherein in the normal area, a width of the first layer of the black matrix, a width of the second layer of the black matrix, and a width of the third layer of the black matrix are same or substantially same.

10. The display device according to claim 1, wherein a width of the first layer of the black matrix in the normal area is greater than a width of the second layer of the black matrix and a width of the third layer of the black matrix.

11. The display device according to claim 10, wherein the width of the second layer of the black matrix and the width of the third layer of the black matrix are same.

12. The display device according to claim 10, wherein a width of the second layer of the black matrix is greater than a width of the third layer of the black matrix.

13. The display device according to claim 12, wherein the black matrix has a step shape.

14. The display device according to claim 12, wherein side surfaces of each of the first layer, the second layer, and the third layer of the black matrix are formed to have an inclined structure having a same inclination, and
the black matrix has a trapezoidal shape.

15. The display device according to claim 1, wherein the optical area includes an optical electronic device configured to operate by receiving light transmitted through the substrate.

16. The display device according to claim 15, wherein in the optical area, the first layer of the black matrix is a long-wavelength visible ray blocking layer, the second layer of the black matrix is a short-wavelength visible ray blocking layer, and the third layer of the black matrix is a layer configured to transmit light having an infrared wavelength.

17. The display device according to claim 16, wherein in the optical area, the first layer of the black matrix comprises at least one selected from blue dye and violet dye,
the second layer of the black matrix comprises at least one selected from yellow dye and orange dye, and
the third layer of the black matrix comprises an organic black material.

18. The display device according to claim 1, wherein the black matrix and the plurality of color filters are disposed above the encapsulation layer, and
the encapsulation layer is a single-layer structure or a multi-layer structure.

19. The display device according to claim 1, further comprising:
an overcoating layer directly on the plurality of color filters and the black matrix.

20. The display device according to claim 1, wherein in the normal area, the refractive index of each of the first layer and the third layer of the black matrix is smaller than the refractive index of the second layer of the black matrix.
